(19) United States
(12) Patent Application Publication
(10) Pub. No.: US 2007/0190773 A1
(43) Pub. Date: Aug. 16, 2007

(54) Method of fabricating a semiconductor device

(76) Inventors: Peter Baars, Dresden (DE); Klaus Muemmler, Dresden (DE); Stefan Tegen, Dresden (DE)

Correspondence Address: SLATER & MATSIL LLP, 17950 PRESTON ROAD, SUITE 1000, DALLAS, TX, 75252, US

(21) Appl. No.: 11/352,446

(22) Filed: Feb. 10, 2006

(51) Int. Cl. H01L 21/4763

(52) U.S. Cl. 438/620; 438/624; 438/738; 438/791

(57) ABSTRACT

According to the invention, the method comprises the steps of: fabricating a first conductive layer including a first contact pad and covering the first conductive layer with a first protection layer at least on top of the first contact pad such that a first protective cap is formed thereon; fabricating a second conductive layer including a second contact pad, wherein the second conductive layer and the first conductive layer are electrically insulated from one another, and covering the second conductive layer with a second protection layer at least on top of the second contact pad such that a second protective cap is formed thereon; depositing at least one intermediate layer on top of the structure; forming a mask on top of the intermediate layer and etching the intermediate layer thereby exposing the first protective cap and the second protective cap, wherein an etchant is applied that provides a larger etch rate with regard to the intermediate layer than with regard to the protective layer; and after exposing the first and second protective caps, etching them and exposing the first and second contact pad during the same etch step.

### TECHNICAL FIELD

The present invention relates to a method of fabricating a semiconductor device. More specifically, the invention relates to a method of fabricating electrical contacts for a semiconductor device such as a memory device.

### BACKGROUND

Complex integrated electronic devices like DRAM memory devices comprise a plurality of conductive layers that are electrically insulated from one another and are disposed in different layer levels or depths having different distances to the substrate's surface. Accordingly, fabricating contacts requires etching contact holes down to the buried conductive layers. However, this is usually quite time-consuming as each contact layer may require a separate handling due to the fact that the depths of the conductive layers may differ considerably.

### SUMMARY OF THE INVENTION

One aspect of the present invention provides a method of fabricating a semiconductor device that allows contacting a plurality of contact pads belonging to different buried conductive layers at the same time.

Another aspect of the present invention avoids damages of the buried conductive layers during etching of the contact holes.

According to embodiments of the present invention, fabricating a semiconductor device includes fabricating a first conductive layer including a first contact pad and covering the first conductive layer with a first protection layer at least on top of the first contact pad such that a first protective cap is formed thereon. A second conductive layer including a second contact pad is fabricated, wherein the second conductive layer and the first conductive layer are electrically insulated from one another. The second conductive layer is covered with a second protection layer at least on top of the second contact pad such that a second protective cap is formed thereon. At least one intermediate layer is deposited on top of the structure. A mask is formed on top of the intermediate layer and the intermediate layer is etched thereby exposing the first protective cap and the second protective cap, wherein an etchant is applied that provides a larger etch rate with regard to the intermediate layer than with regard to the protective layer. After exposing the first and second protective caps, the first and second contact pads are etched and exposed during the same etch step.

According to embodiments of the invention, each contact pad of the conductive layers is individually protected by a protective cap. When electrical contacts are provided for the buried contact pads, contact holes are etched in a two-step-manner. In a first step, the intermediate layers on top of each protective cap are removed. Then, after exposing the protective caps (i.e., in a second step), the caps are removed and the buried contact pads are exposed. Therefore, according to embodiments of the invention, a plurality of contact pads belonging to different conductive layers in different depths may be exposed and subjected to metallization at the same time. This allows using a single etch mask for providing contacts to differently deep contact pads. Additionally, the removal of the protective caps proceeds in an identical manner for all pads independently of their individual depth. Therefore, damages of buried contact pads due to any sort of overetching are avoided.

According to a preferred embodiment of the invention, the first protection layer and the second protection layer may be fabricated simultaneously during the same fabrication step.

Alternatively, the semiconductor device is fabricated in or on a substrate such that the first conductive layer and the second conductive layer have different distances relative to the substrate's surface.

The first conductive layer may be fabricated inside the substrate below the substrate's surface. The second conductive layer may be fabricated above the substrate's surface.

Preferably the semiconductor device is a memory device comprising an array part with a plurality of memory cells. The first conductive layer may form a buried word line of the memory device and the first contact pad may form a buried word line contact pad. The second conductive layer may form a bit line of the memory device and the second contact pad may form a bit line contact pad.

Usually memory devices comprise a driving circuit being placed in a peripheral part of the devices located outside the array part. In this case, it is preferred that the second conductive layer simultaneously forms a gate contact layer of at least one transistor of the driving circuit.

In the latter case the method may further include covering the second conductive layer with the second protection layer also on top of the gate contact pad such that an additional protective cap is formed thereon; etching the intermediate layer and exposing the first protective cap, the second protective cap and the additional protective cap during the same etch step; and after exposing the protective caps, etching all of them and exposing all contact pads during the same etch step.

With regard to the driving circuit, it is further considered advantageous if the method includes fabricating a third conductive layer including source and drain contact pads for the at least one transistor of the driving circuit; and covering the third conductive layer with a third protection layer at least on top of the source and drain contact pads such that third protective caps are formed thereon.

The third conductive layer may be fabricated such that the upper surface of the third conductive layer is located further apart from the substrate's surface than the upper surface of the first and second conductive layers.

Preferably the method further includes depositing the intermediate layer on top of the third protection layer; structuring the intermediate layer and exposing the first protective cap, the second protective cap, the additional protective cap and both third protective caps during the same etch step; and after exposing the protective caps, etching all of them and exposing all underlying contact pads during the same etch step.

The source and drain contacts of at least one transistor of the driving circuit may be fabricated in a self-aligned fashion using a sacrificial layer consisting of or containing polysilicon, amorphous silicon, SiGe-material and/or carbon.

According to an alternative embodiment of the invention, the method includes etching the second protective layer using an etch mask and exposing the gate contact pad at least partly before the third conductive layer is fabricated enabling the third conductive layer to be located directly above and in contact with the exposed gate contact pad; and covering the third conductive layer with the third protection layer also at least on top of the gate contact pad.

The third protection layer and the underlying third conductive layer may be etched such that the gate contact pad, the source contact pad and the drain contact pad are electrically separated from another before depositing the intermediate layer. After depositing the intermediate layer this layer is preferably etched using an etch mask exposing the first protective cap, the second protective cap, the additional protective cap and both third protective caps during the same etch step; and after exposing the protective caps, they are etched and all underlying contact pads are exposed during the same etch step.

Preferably, the first protection layer and the second protection layer are fabricated simultaneously and the third protection layer is fabricated thereafter. The first protective layer, the second protective layer and the third protective layer may consist of or contain silicon nitride; and the intermediate layer may consist of or contain silicon oxide.

### BRIEF DESCRIPTION OF THE DRAWINGS

In order that the manner in which the above-recited and other advantages and aspects of the invention are obtained will be readily understood, a more particular description of the invention briefly described above will be rendered by reference to specific embodiments thereof, which are illustrated in the appended drawings. Understanding that these drawings depict only typical embodiments of the invention and are, therefore, not to be considered to be limiting its scope, the invention will be described and explained with additional specificity and detail through the use of the accompanying drawings in which:

FIG. 1A shows an exemplary memory device;

FIGS. 1B-16F show a first example of a method according to the present invention for fabricating contacts for the device shown in FIG. 1A; and

FIGS. 17A-22F show a second example of a method according to the present invention for fabricating contacts for the device shown in FIG. 1A.

The following list of reference symbols can be used in conjunction with the figures:
1 memory device
2 array part
5 bit line
10 word line
15 active area line
20 isolation trenches
25 bit line connection
30 node connection
35 isolation gate line
50 silicon substrate
55 substrate's surface
60 silicon nitride layer
65 silicon oxide
70 peripheral part
75 edge part
80 first conductive layer
85 first contact pad=buried word line contact pad
95 oxide
105 nitride
106 oxide
110 second conductive layer
120 polysilicon layer
125 metal layer
130 gate contact layer
135 resist or hard mask
140 protection layer
145 first protection layer
150 first protective cap
155 second protection layer
160 second contact pad=bit line contact pad
165 second protective cap
170 silicon oxide layer
171 resist mask layer
175 structured gate contact layer
180 gate contact pads
181 additional protective cap
185 oxide layer
190 polysilicon
195 stud area
200 grooves
205 oxide
210 nitride liner
215 CoSi contacts
220 source/drain areas
225 transistor
230 third conductive layer
235 source and drain contact pads
240 third protection layer
245, 250 third protective caps
255 intermediate layer
260 capacitors
265 metallization layer
270 gate contact
275 source contact
280 drain contact
285 contact the buried word line contact pad
290 contact for the bit line contact pad
300 mask layer
305 third conductive layer
310 source contact pads
315 drain contact pads
320 nitride layer
325 resist or hard mask
330 third protection layer
335 third protective cap
340 third protective cap

### DETAILED DESCRIPTION OF ILLUSTRATIVE EMBODIMENTS

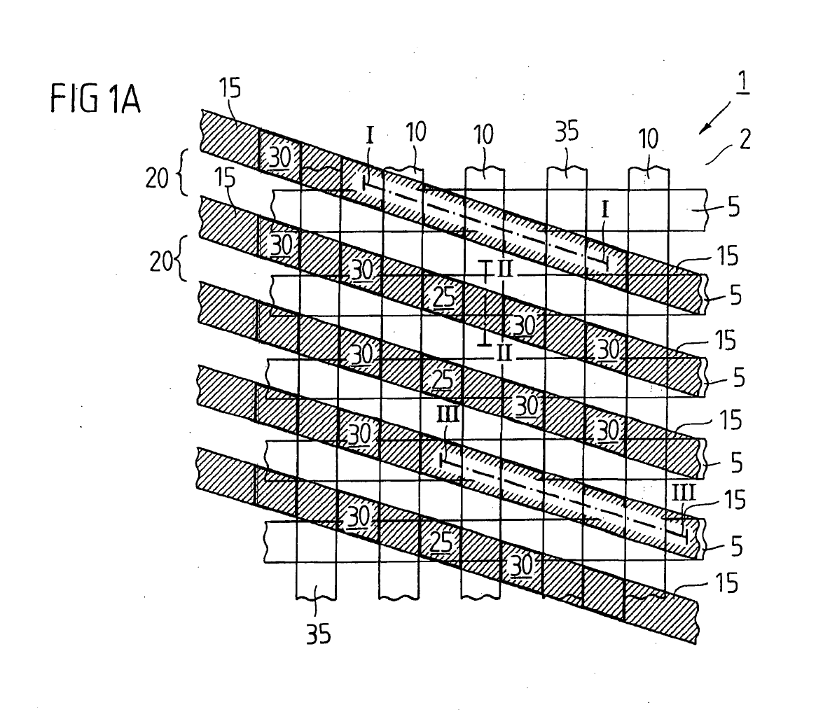

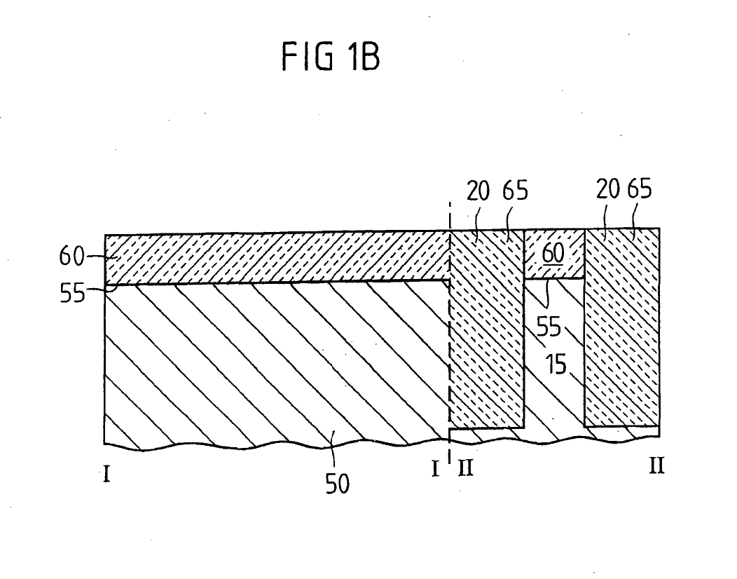

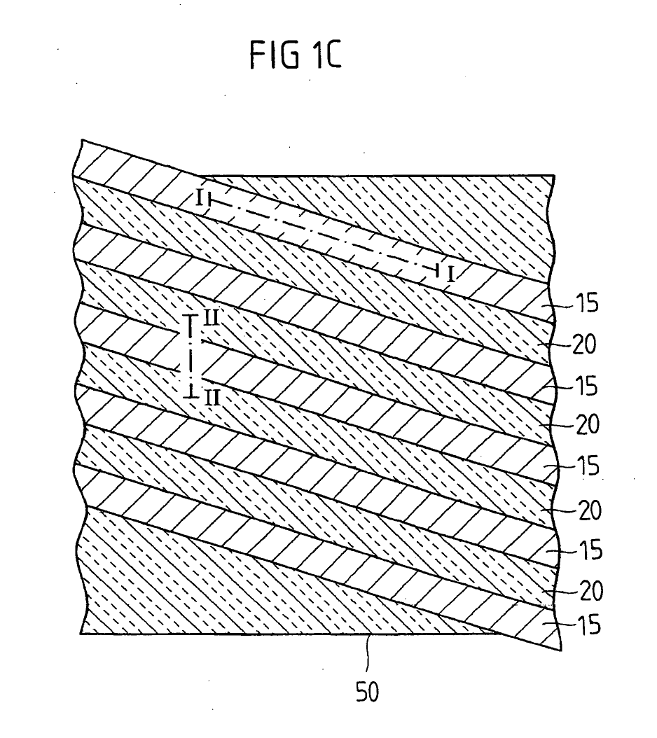

FIG. 1A shows an exemplary embodiment of a memory device 1, which the description given below will refer to when explaining the inventive method in detail with reference to FIGS. 1B-22F.

FIG. 1A shows an array part 2 of the memory device 1. A plurality of bit lines 5 are formed along a horizontal direction, whereas a plurality of buried word lines 10 are arranged in a second direction, which is preferably perpendicular to the first direction. In addition, continuous active area lines 15 are disposed at a slanted angle with respect to the bit lines 5 and the word lines 10, respectively. As is shown in FIG. 1A, the bit lines 5 as well as the word lines 10 are implemented as straight lines.

Usually, the active area lines 15 are defined by forming isolation trenches 20 which are filled with an insulating material, in a semiconductor substrate such as a silicon substrate. Accordingly, the active area lines 15 are separated and electrically insulated from each other. At an intersection of an active area line 15 and a bit line 5, a bit line connection 25 is formed. Moreover, node connections 30 are formed at those portions of the active area lines 15 that are not covered by a bit line 5 nor by a word line 10. The node connections 30 provide an electrical contact between an access transistor and a corresponding storage capacitor. Usually, the storage capacitor is formed on top of the shown semiconductor surface.

As shown in FIG. 1A, an isolation gate line 35 is disposed between pairs of neighboring word lines 10. In a cross-section taken along I-I, the word lines 10 and the isolation gate lines 35 are disposed above the active area lines 15.

Transistors are formed in the active area lines 15, wherein the transistors comprise a first source/drain region, a second source/drain region as well as a channel connecting first and second source/drain regions. The conductivity of the channel between the first and the second source/drain regions is controlled by the word lines 10 and the isolation gate line 35. In particular, an appropriate voltage is applied to the isolation gate line 35, so that no current flows beneath the isolation gate line. Accordingly, an electrical insulation between neighboring pairs of memory cells is achieved by the isolation gate line. The first and the second drain regions are arranged beneath the bit line connections 25 and the node connections 30, respectively.

As shown in FIG. 1A, the word lines 10, the isolation gate lines 35 and the bit lines 5 are arranged in a regular manner so as to form a grid. In the arrangement shown in FIG. 1A, two adjacent transistors share a common bit line connection 25, as will also be explained later.

FIGS. 1B to 16F illustrate the first exemplary embodiment of the inventive method of forming electrical contacts for the memory device 1 as shown in FIG. 1A.

FIG. 1B shows a plan view of the array part 2 of the silicon substrate 50 after etching the active area lines 15. In FIG. 1B, the left hand side shows the cross-section along the active area between I and I (see FIG. 1C), whereas the right hand side of FIG. 1B shows the cross-section perpendicular to the active area line 15 (see line II-II of FIG. 1C).

On top of the active area line 15, the substrate's surface 55 is covered with a silicon nitride layer 60 whereas the isolation trenches 20 and other areas of the substrate 50 are covered with silicon oxide 65.

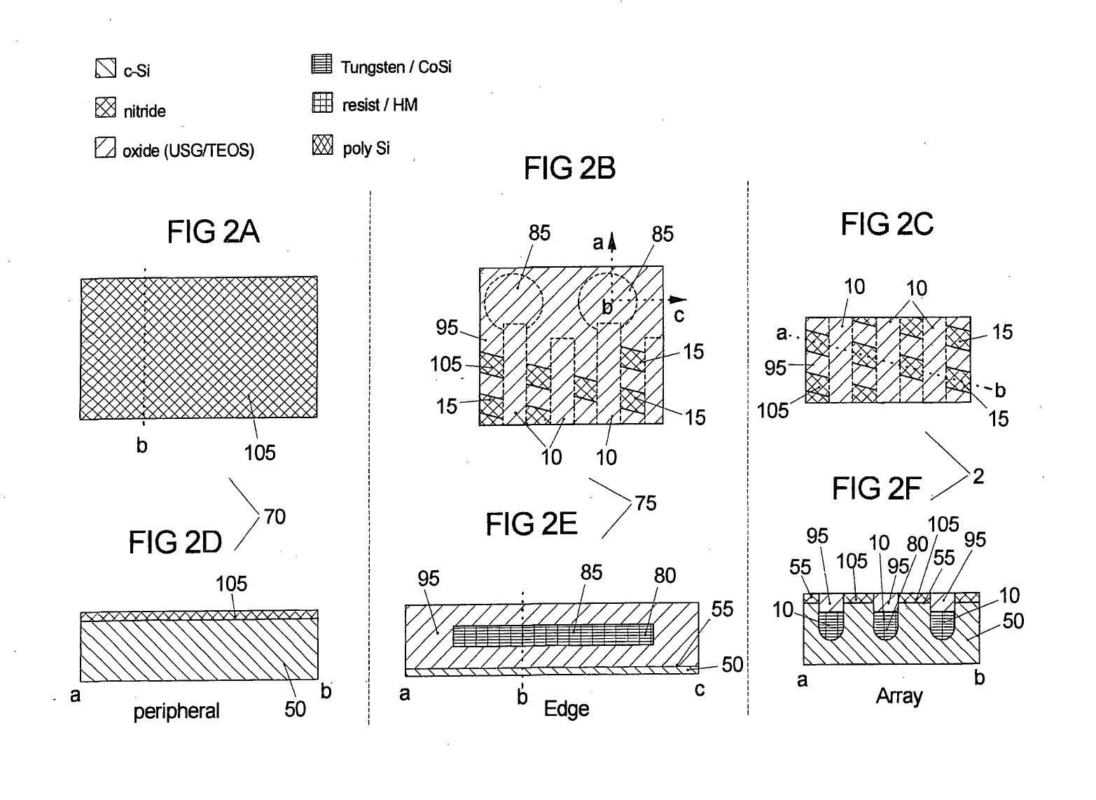

On the pages showing FIGS. 2A-22F, the figures in the upper part of each page show a plan view of the memory device 1. The figures in the lower part of each page show cross-sections relating to the corresponding figures thereabove.

The figures on each upper left hand side (indicated by suffix “A”) refer to a peripheral part 70 of the memory device 1, which comprises a driving circuit with at least one transistor. The figures on each lower left hand side designated by suffix “D” show a cross section of the peripheral part 70 of the memory device 1 as defined by a line in the corresponding “A”-figure.

The figures in the middle of each page (indicated by suffixes “B” and “E”) refer both to an edge part 75 of the memory device 1 comprising pads for connecting the buried word lines and the bit lines, which pass the array part 2 of the memory device 1. Accordingly, the figures designated by suffixes “B” and “E” show a plan view of the edge part 75 and a cross-section thereof, respectively.

The figures on the right hand side of each page (indicated by suffixes “C” and “F”) refer to the array part 2 comprising the active memory cells of the memory device 1. Accordingly, the figures designated by suffixes “C” and “F” show a plan view of the array part and a cross-section thereof, respectively.

In FIGS. 2A-2F, the substrate 50 is depicted after fabricating a first conductive layer 80 including a first contact pad 85. The first conductive layer 80 forms the buried word lines 10 of the memory device 1 in the array part 2 (FIG. 2F). The first contact pad 85 forms a buried word line contact pad (also referred to as word line landing pad hereinafter) in the edge part 75 of the memory device 1 (see FIG. 2E). As can be seen in FIG. 2F, the buried word lines 10 are fabricated inside the substrate 50 below its upper surface 55. Accordingly, the word line contact pad 85 in the edge part 75 of the memory cell is also situated below the upper substrate's surface 55 as can be seen by comparing FIGS. 2E and 2F.

It can also be seen that the first conductive layer 80 is covered with an oxide 95 whereas the substrate's surface 55 in the array part 2 and the peripheral part 70 is covered with a nitride layer 105.

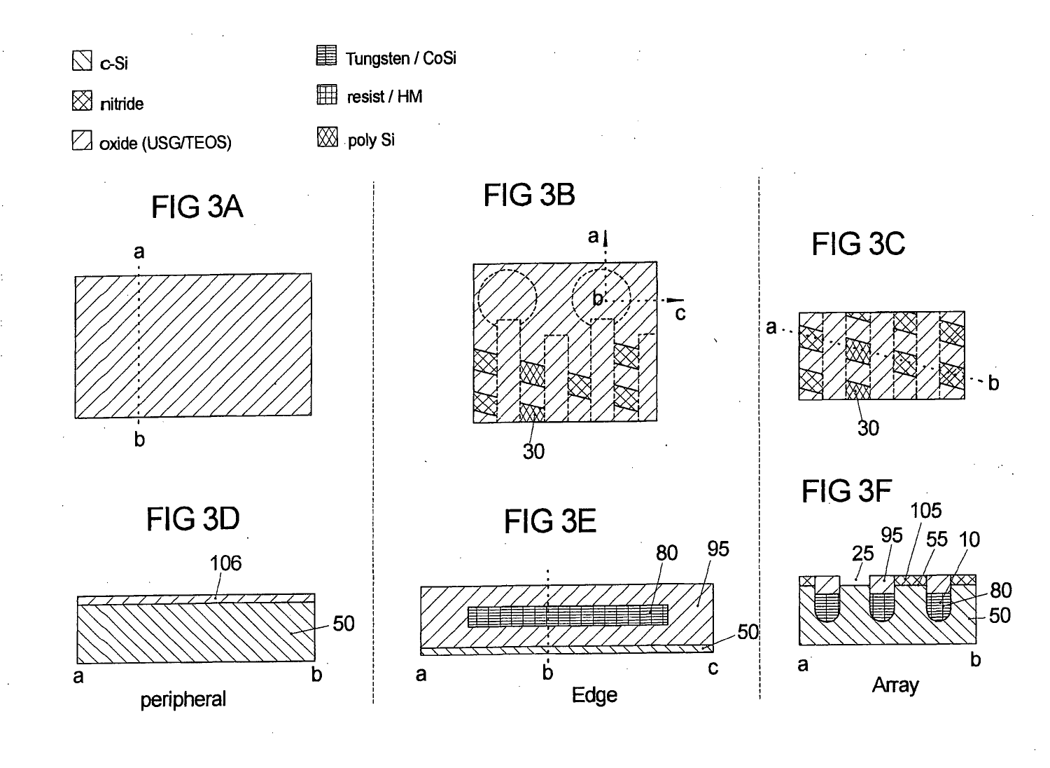

In FIGS. 3A-3F, the structure is shown after removing the nitride 105 in the active area in places where the bit connections 25 (FIG. 1A) lines 5 will be fabricated (FIGS. 3B, 3C, 3F). Additionally, the nitride 105 in the peripheral part 70 is replaced by an oxide 106 (FIG. 3D).

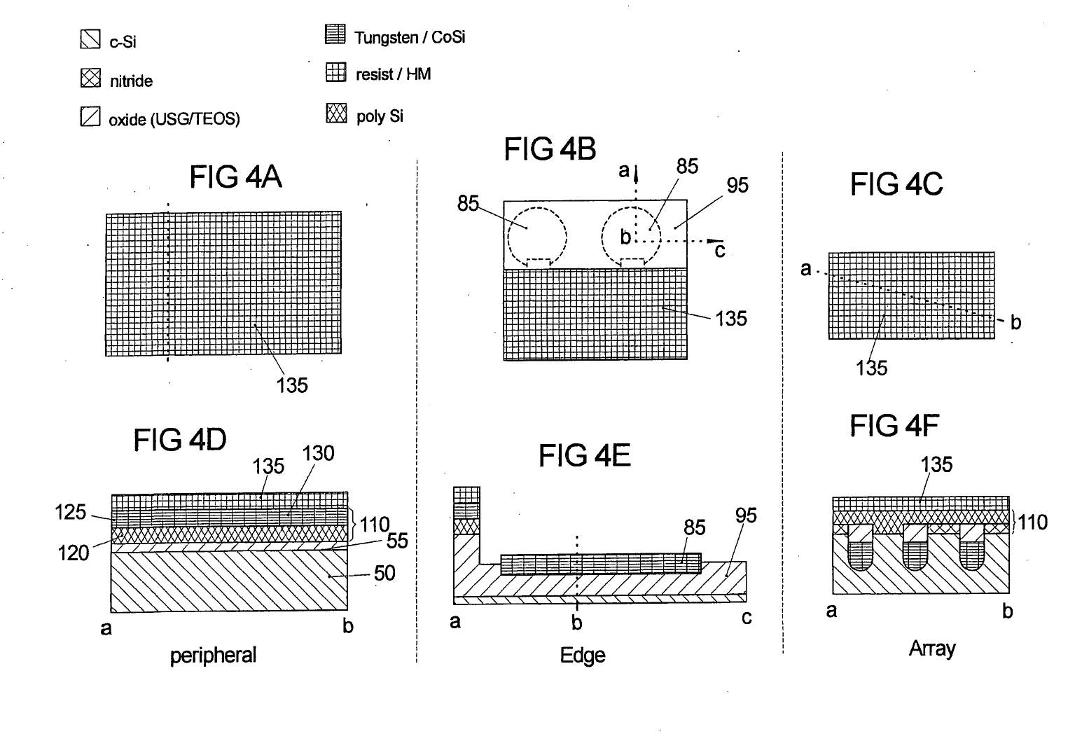

In FIGS. 4A-4F, the structure is shown after fabricating a second conductive layer 110. The second conductive layer 110 and the first conductive layer 80 are electrically insulated from one another. The second conductive layer 110 may consist of, e.g., a polysilicon layer 120 and a metal layer 125. The second conductive layer 110 will form the bit lines 5 of the memory device 1 and the bit line connections 25 in the array part 2 as shown in FIG. 1A. The second conductive layer 110 also forms a gate contact layer 130 for transistors of a driving circuit being placed in the peripheral part 70 of the substrate 50 located outside the array part 2.

In order to isolate the substrate's surface 55 in the peripheral part 70 from the second conductive layer 110, the oxide layer 106 has been deposited thereon before fabricating the second conductive layer 110. As will be seen below, the oxide layer 106 will form a gate oxide layer for the transistors in the peripheral part 70.

Thereafter, a resist or hard mask 135 is formed on the second conductive layer 110. The resulting structure is etched and the buried word line contact pad 85 is exposed in the edge part 75 (FIG. 4E).

Then, the mask 135 is removed and a protection layer 140 consisting of silicon nitride is deposited. This protection layer 140 forms a first protection layer 145 in the edge part 75 including a first protective cap 150 that protects the buried word line contact pad 85.

The protection layer 140 simultaneously forms a second protection layer 155 that protects the future bit line 5 in the array part 2. The area of the second protection layer 155 that is situated on top of a future bit line contact pad 160 of the bit line 5 will be referred to as second protective cap 165 hereinafter.

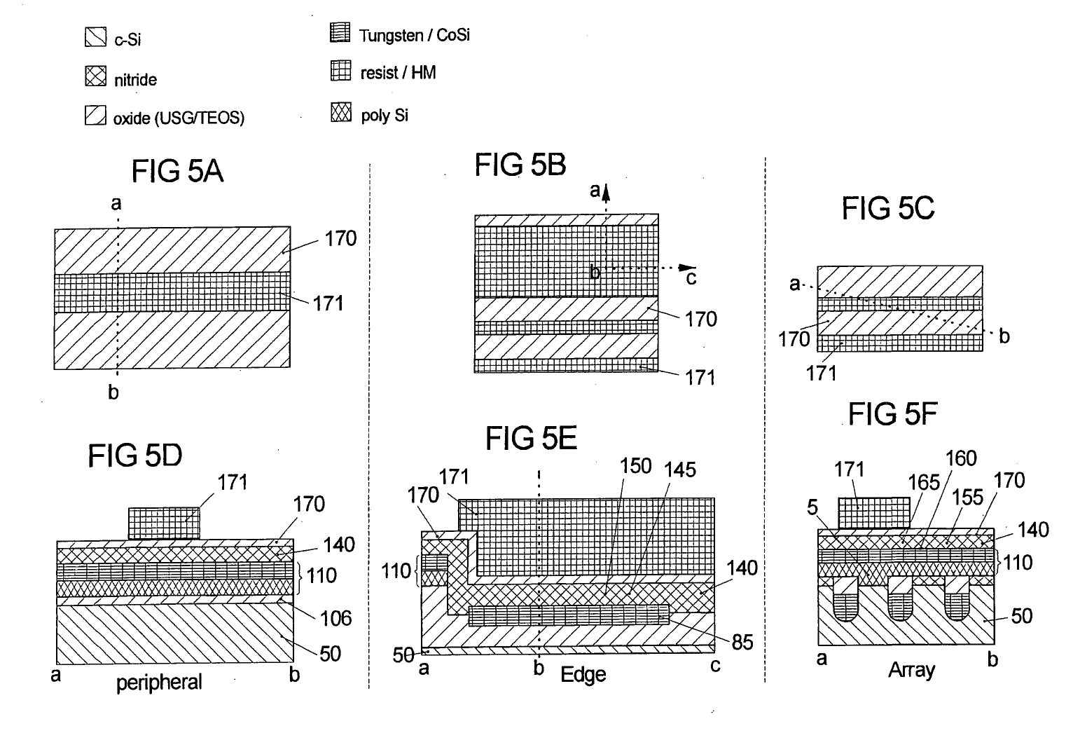

After forming the first and second protective caps 150 and 165, the protection layer 140 is covered with a silicon oxide layer 170 and a resist mask layer 171. The resist mask layer 171 is structured as shown in FIGS. 5D, 5E, and 5F.

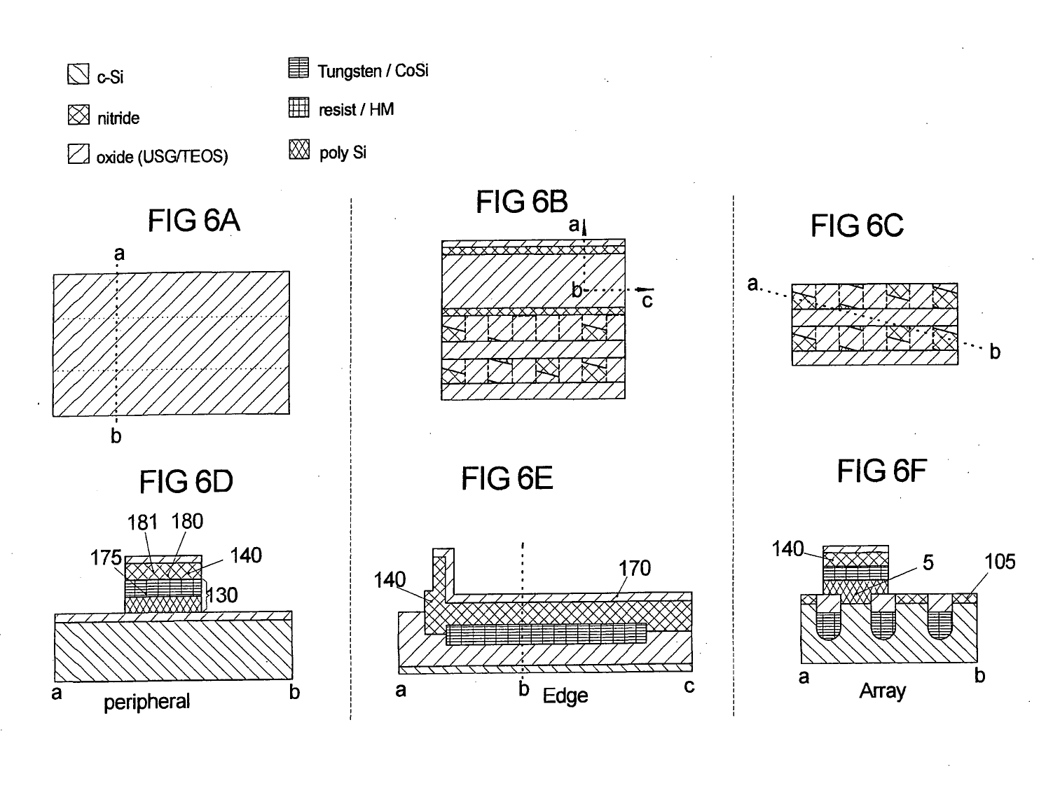

By etching the resulting structure, the gate contact layer 130 in the peripheral part 70 is structured forming a structured gate contact layer 175 and gate contact pads 180 for the transistors of the driving circuit (FIG. 6D). During this etch step, additional protective caps 181 are formed by the protection layer 140 on top of the gate contact pads 180 (FIG. 6D). Simultaneously, the bit lines 5 in the array part 2 are completed during this etch step (FIG. 6F). The edge part 75 however remains mainly covered by oxide layer 170.

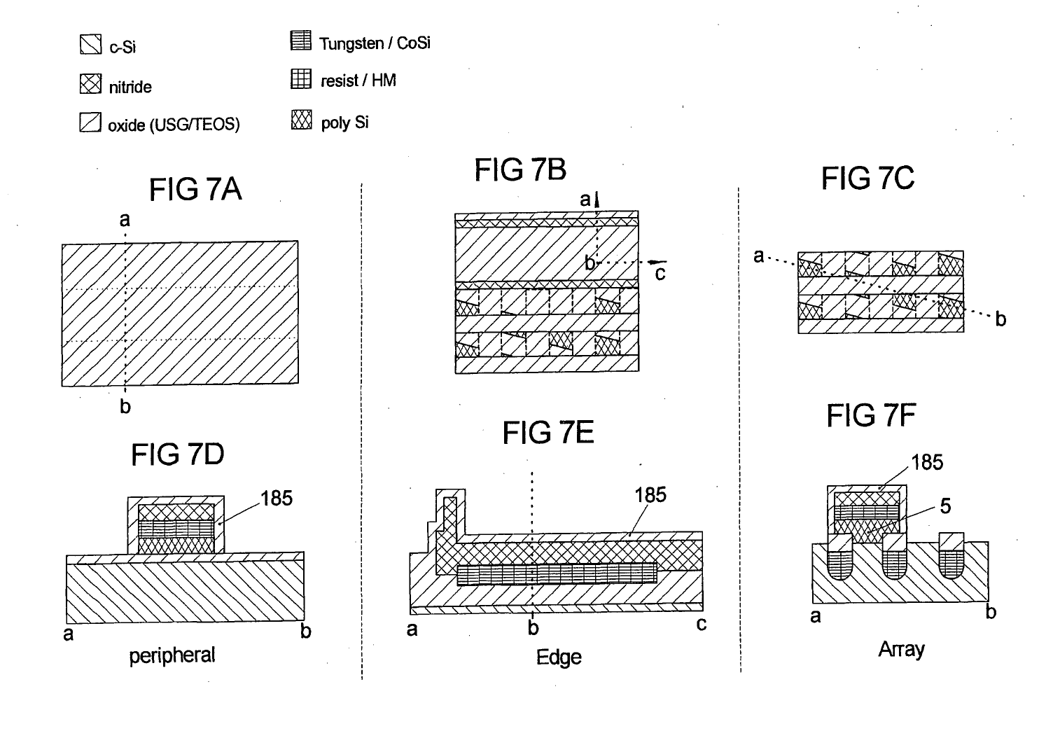

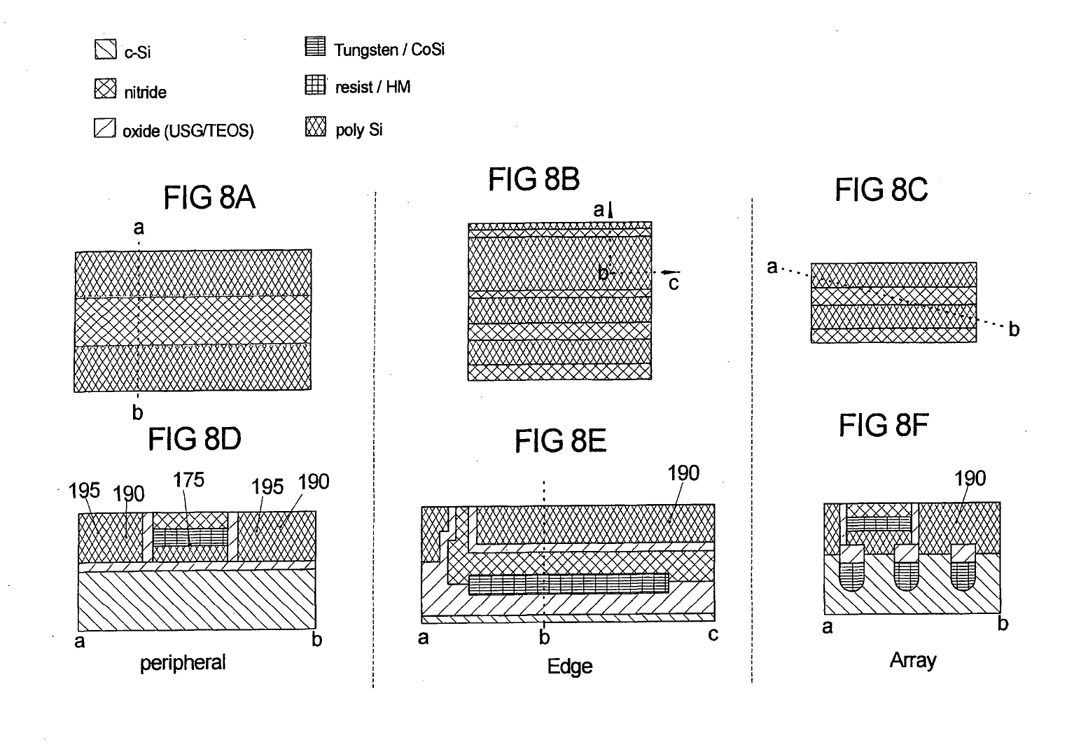

Thereafter, an oxide layer 185 is deposited and subjected to an anisotropic etch step which removes the horizontal part of the oxide layer 185 in the array part 2 outside the bit line 5 (FIGS. 7A-7F). Then, the nitride layer 105, which is partly remaining on top of the active areas in the array is removed by means of dry or wet etching. Now, polysilicon 190 is deposited and the structure is subjected to a CMP (chemical mechanical polishing) step (FIGS. 8A-8F). Adjacent to the gate contact layer 175, the polysilicon layer 190 forms a sacrificial layer with sacrificial stud areas 195 that will serve to fabricate self-aligned source and drain contacts for the transistors in the peripheral part 70 of the device.

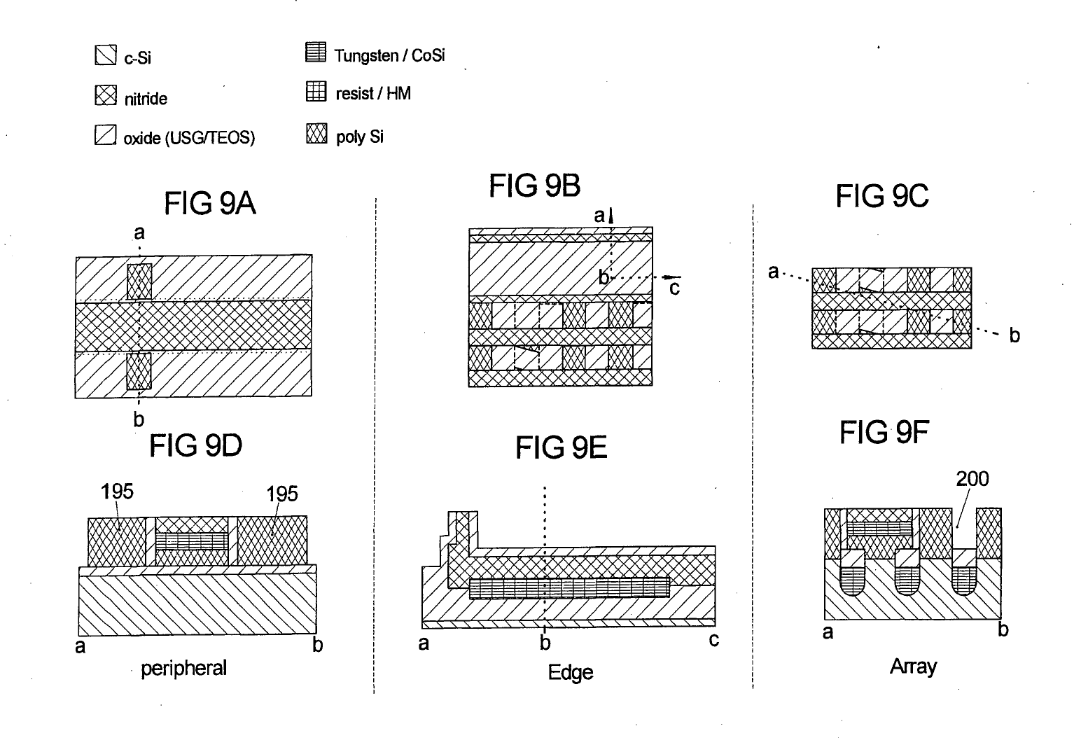

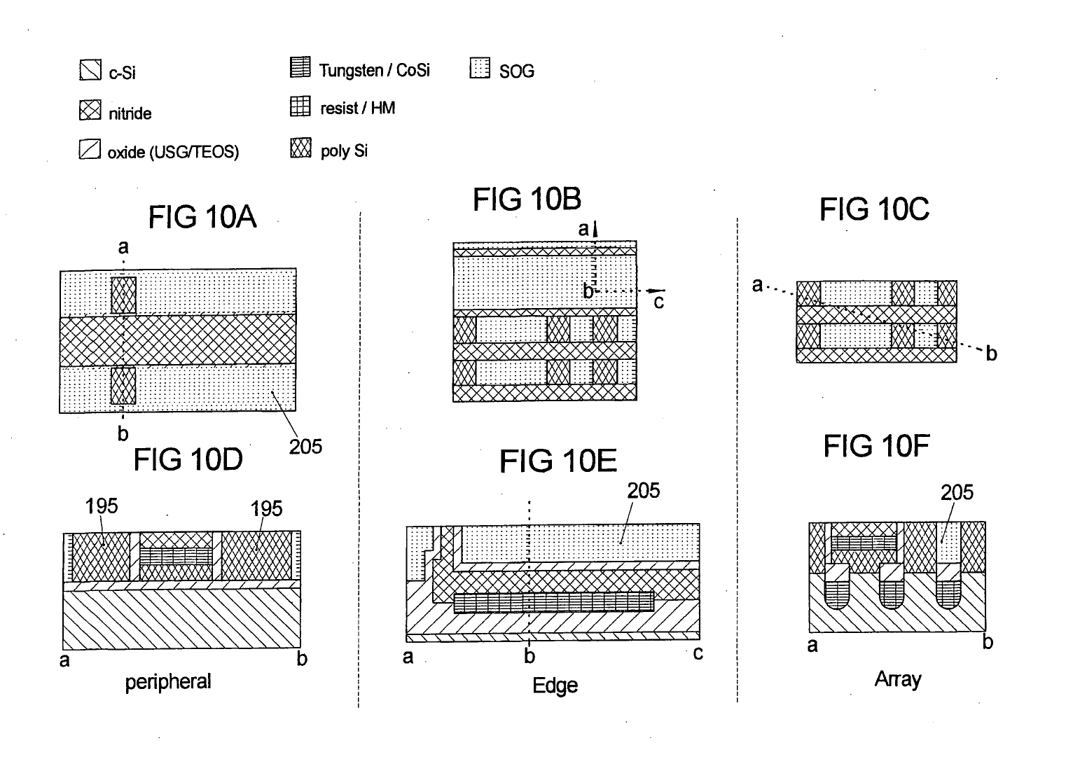

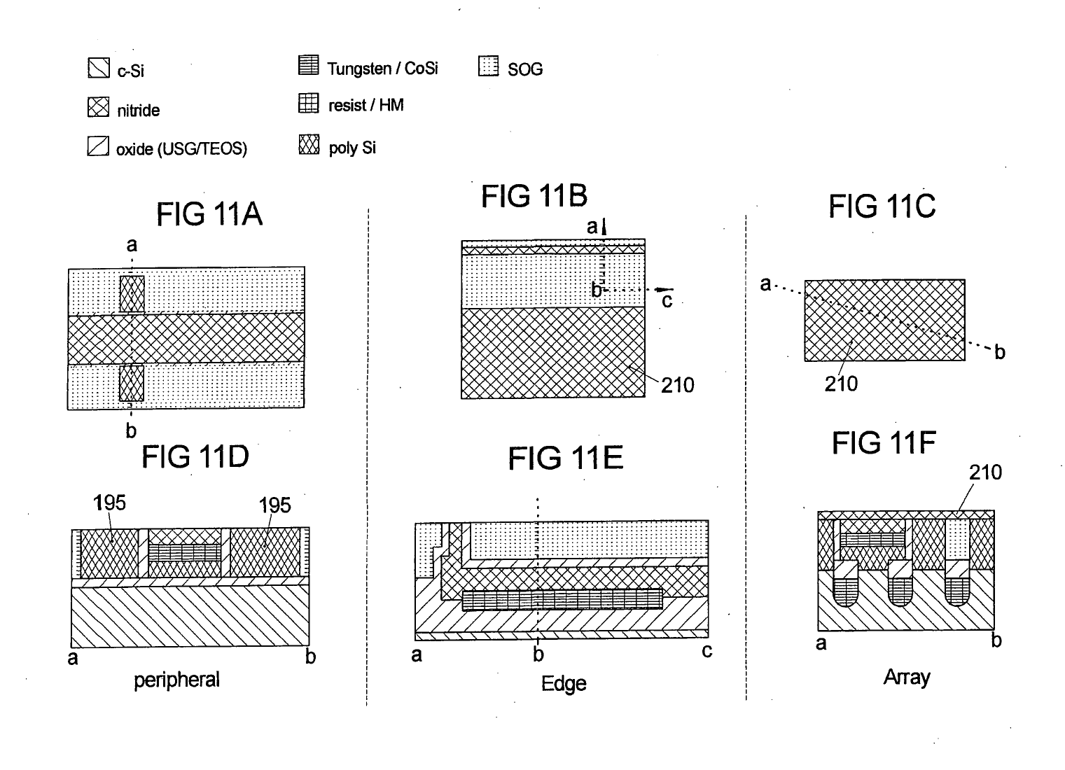

FIGS. 9A-9F visualize an etch step forming grooves 200 for the isolation gate lines 35 as mentioned above with regard to FIG. 1A. The grooves 200 are filled with an oxide 205 (e.g., SOG(spin-on-glass)-oxide) as shown in FIG. 10F. Thereafter, the array part 2 is covered with a nitride liner 210 (FIGS. 11A-11F).

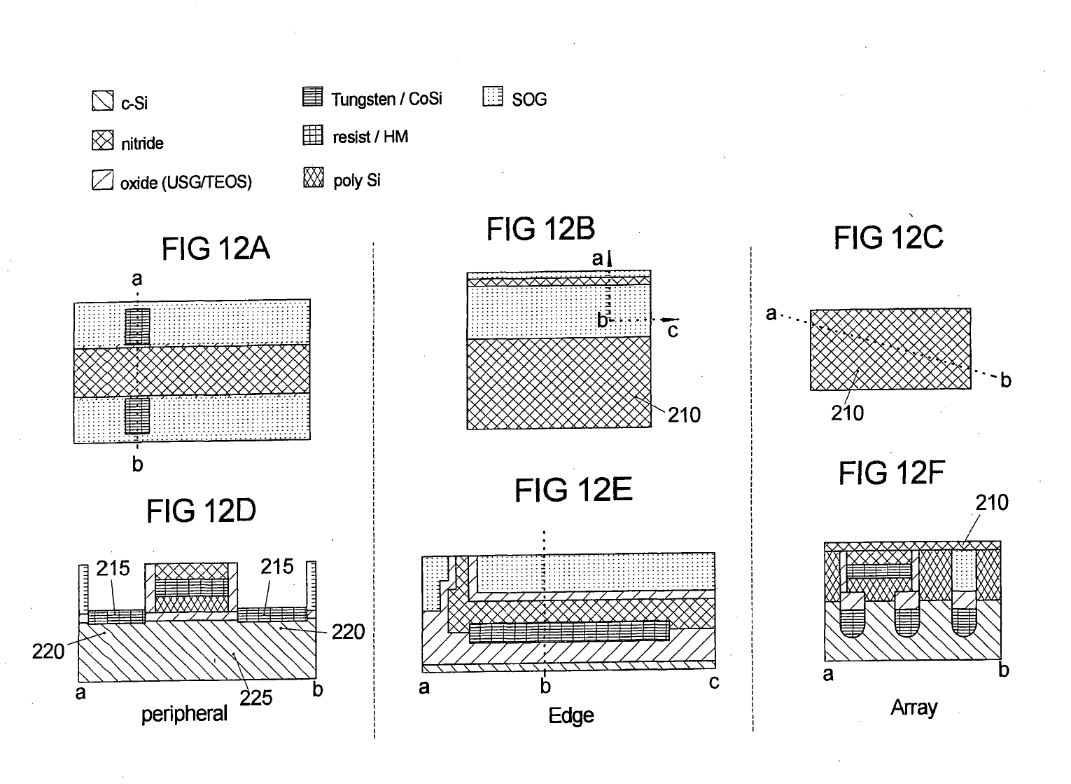

In FIGS. 12A-12F, the structure is shown after removing the sacrificial stud areas 195 in the peripheral part 70 of the device and fabricating silicide contacts (e.g., cobalt or titanium silicide contacts) 215 in the source and drain areas 220 of the transistors 225 in the peripheral part 70.

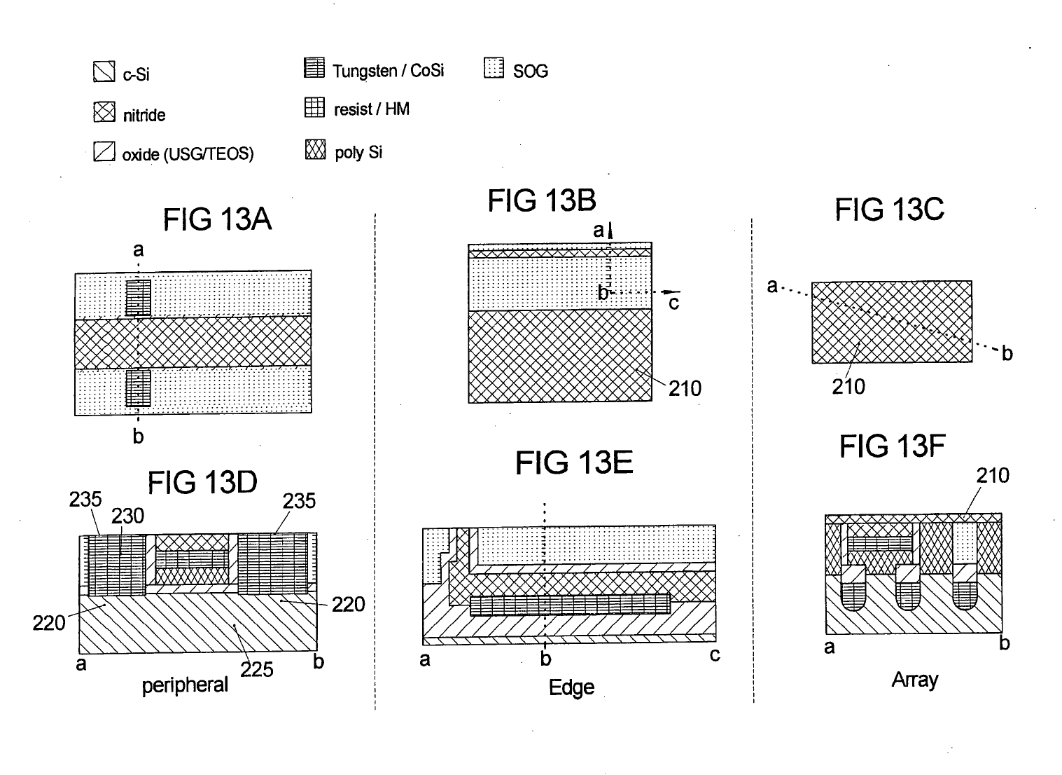

The previous stud areas 195 are then filled with a third conductive layer 230 of metal such as Tungsten or CoSi and the structure is polished in a CMP step (FIGS. 13A-13F). The third conductive layer 230 includes source and drain contact pads 235 for later contacting the transistors 225.

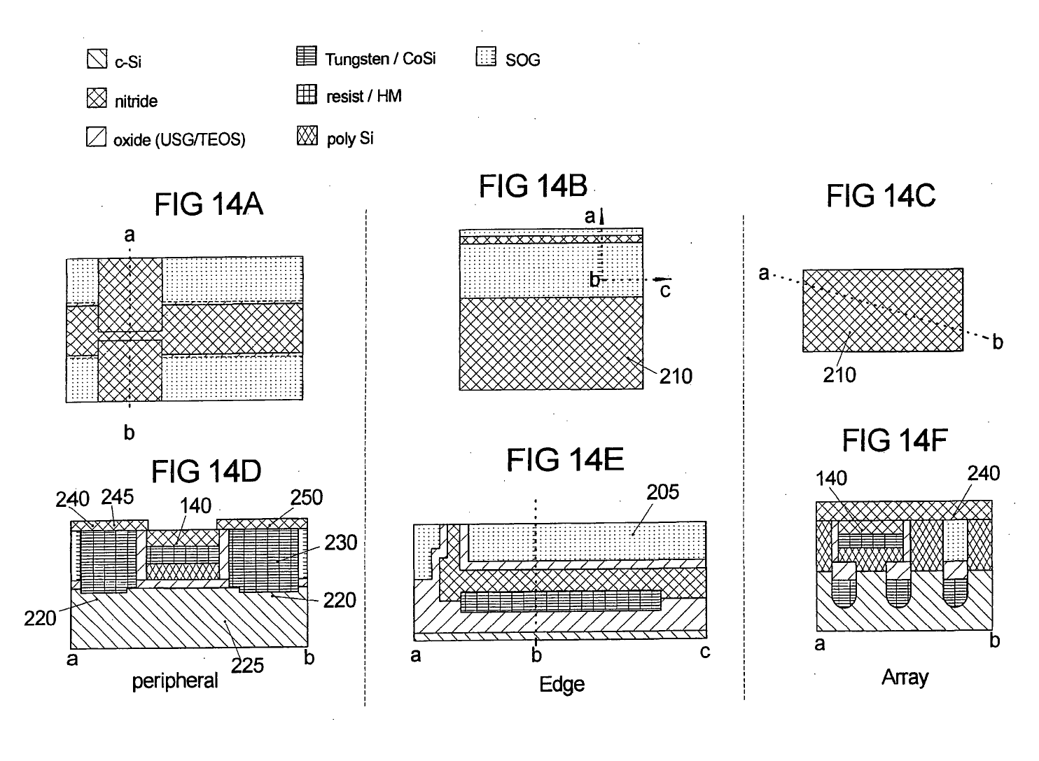

In FIGS. 14a-14F, the structure is depicted after depositing a third protection layer 240 (e.g., a silicon nitride layer) on top of the third conductive layer 230 and on top of the protection layer 140 placed in the peripheral part 70 and the array part 2. The third protection layer 240 forms two third protective caps 245 and 250, one placed on top of the source contact and another one placed on top of the drain contact of the transistors in the peripheral part 70. Preferably, the third protection layer 240 has the same thickness as the first protection layer 140.

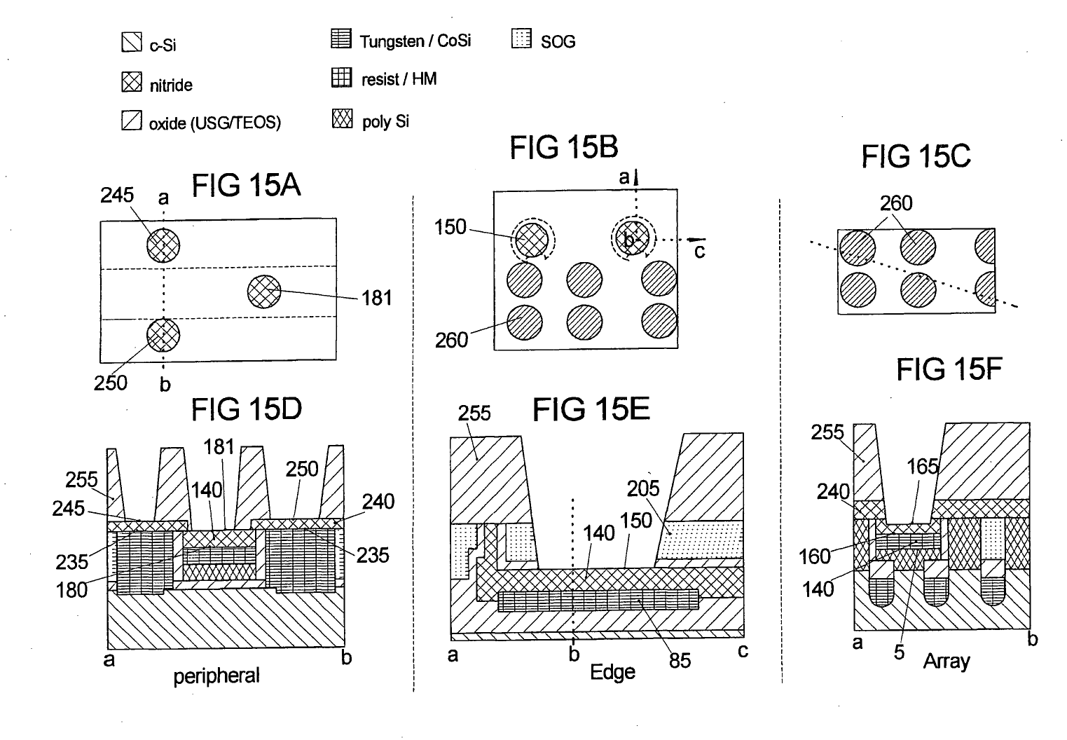

Then, an intermediate layer 255 (e.g., an oxide layer) is deposited on top of the third protection layer 240 and is structured such that the first protective cap 150, the second protective cap 165, the additional protective cap 181 and the third protective caps 245 and 250 are exposed during the same etch step. During this etch step, an etchant is used that selectively etches the intermediate layer 255 and the oxide 205 faster than the protection layers 240 and 140 (FIGS. 15E-15F). FIG. 15B also shows capacitors 260 being part of the memory cells in the array part 2 of the device for storing information. FIG. 15F refers to a different cross section and therefore does not show these capacitors.

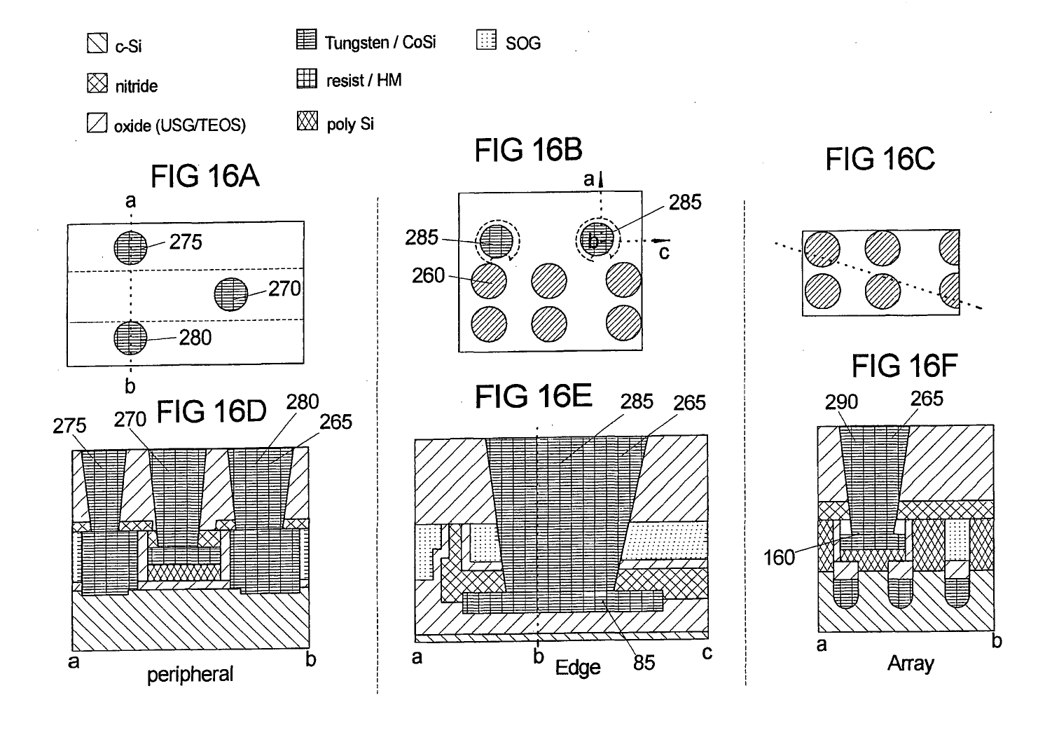

After exposing the protective caps 150, 165, 181, 245 and 250, they are etched and the underlying contact pads 85, 160, 180 and 235 are exposed (FIGS. 15A-15F). This allows filling a metallization layer 265 for contacting the exposed contact pads. Thereby in a single step, a gate contact 270, a source contact 275, and a drain contact 280 are completed in the peripheral part of the device. At the same time, a contact 285 for the buried word line contact pad 85 and a contact 290 for the bit line contact pad 160 are completed (FIGS. 165A-16F). For illustration reasons only, the gate contact 270 and the bit line contact 290 are drawn in FIGS. 15D/16D and FIGS. 15F/16F, respectively. In fact, neither is located along the shown cross-sections.

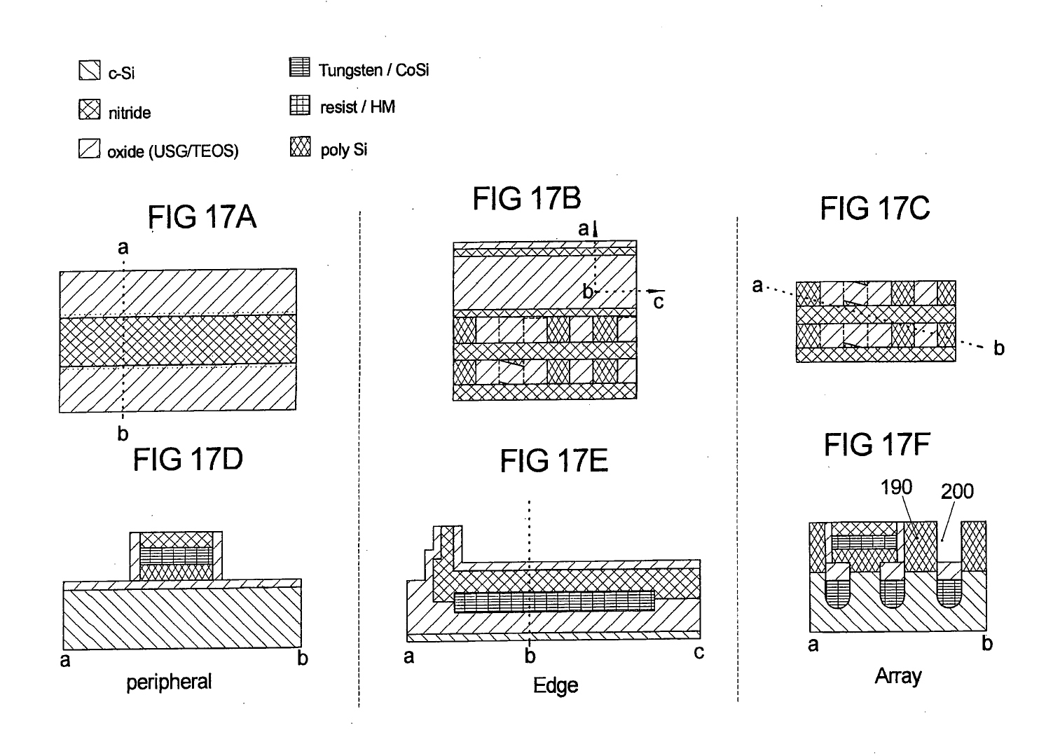

FIGS. 17A-22F refer to a second embodiment of the invention. Starting from the structure depicted in FIGS. 8A-8F, grooves 200 are fabricated inside the polysilicon 190 in the array part 2 as explained above. However, in contrast to the first embodiment, the polysilicon 190 is also removed in the peripheral part 70. Accordingly, no sacrificial layer is formed by the polysilicon 190 for self-aligned source/drain contacts.

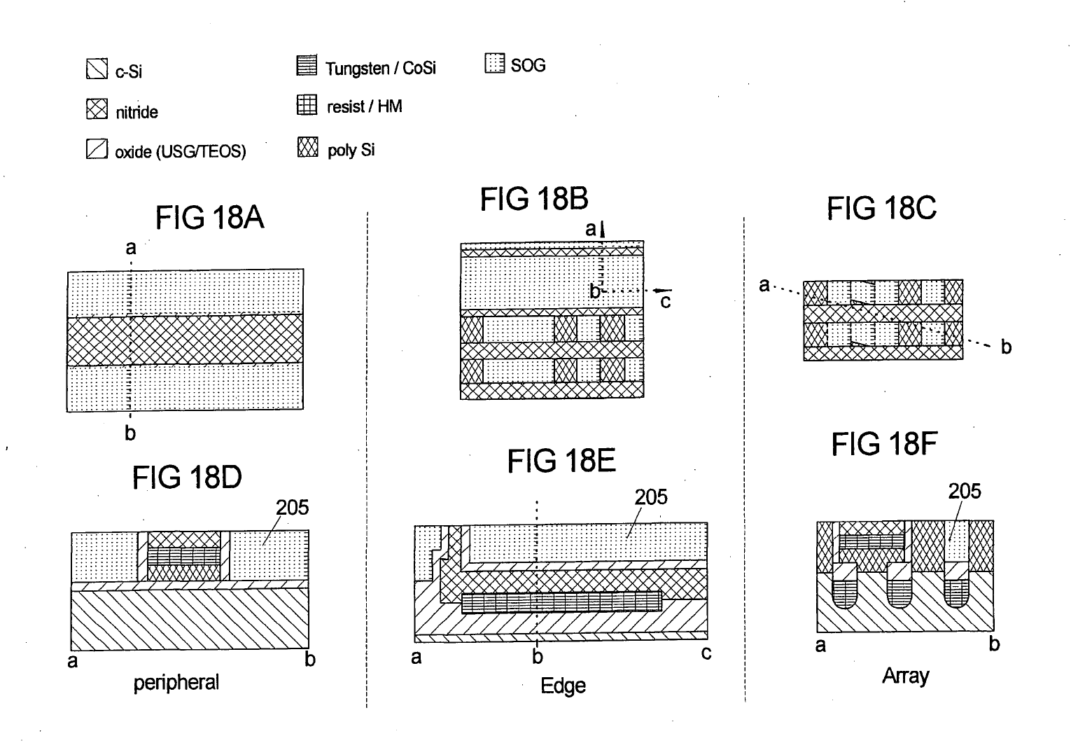

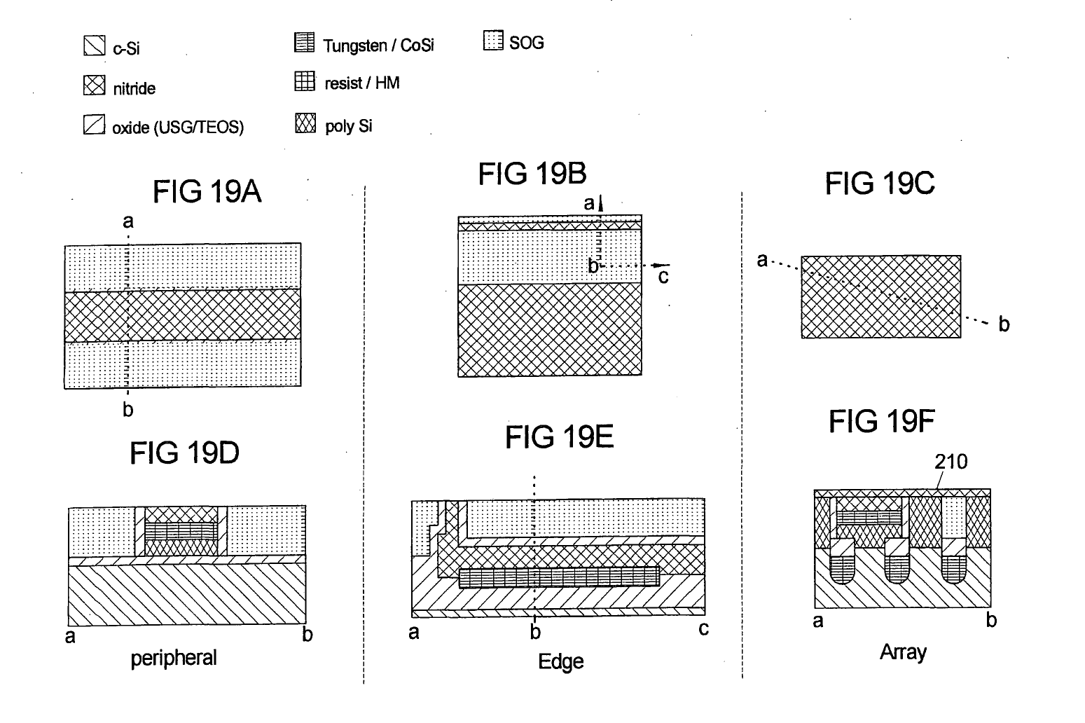

Thereafter, an oxide layer (e.g., SOG(spin-on-glass)-oxide) 205 is deposited and subjected to a CMP-step. The resulting structure is shown in FIGS. 18A-18F. Then, the array part 2 is covered with a nitride liner 210 (FIGS. 19A-19F).

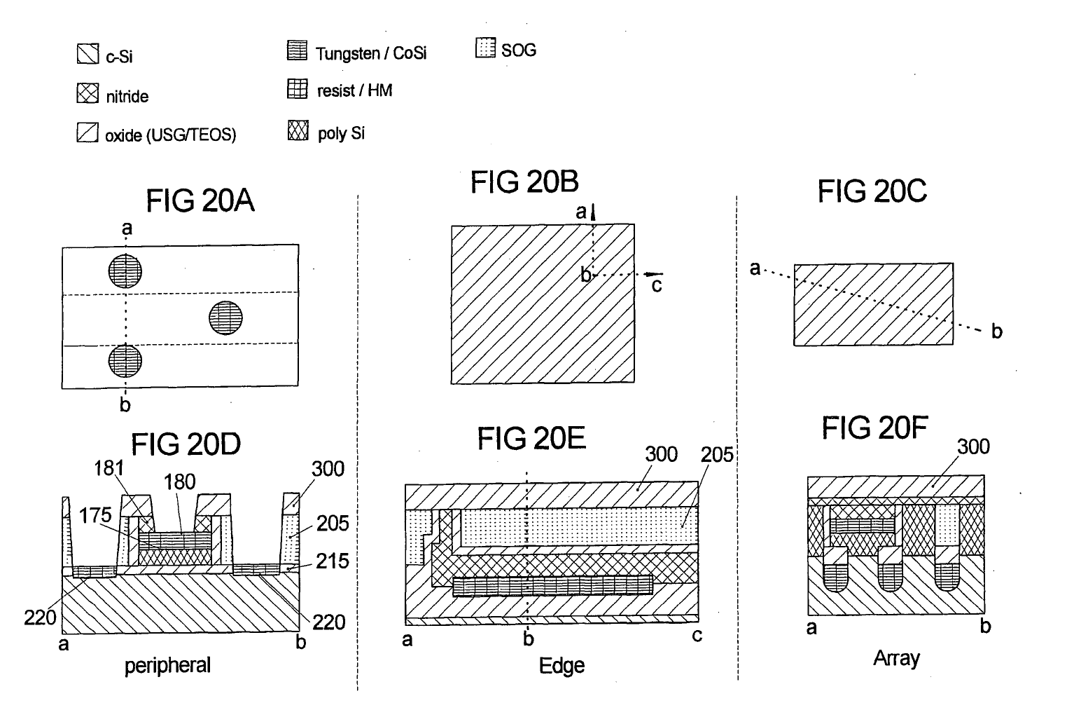

In FIGS. 20A-20F, the memory device 1 is shown after depositing an oxide mask layer 300. The oxide mask layer 300 is opened in the peripheral part 70 as sketched in FIG. 20D in order to allow etching of the additional protective caps 181 on top of the gate contact pads 180 and exposing the gate contact pads 180 at least partly. At the same time, the oxide layer 205 is opened above the source/drain areas 220. Then CoSi-contacts 215 are formed on top of the source/drain areas 220 (FIG. 20D).

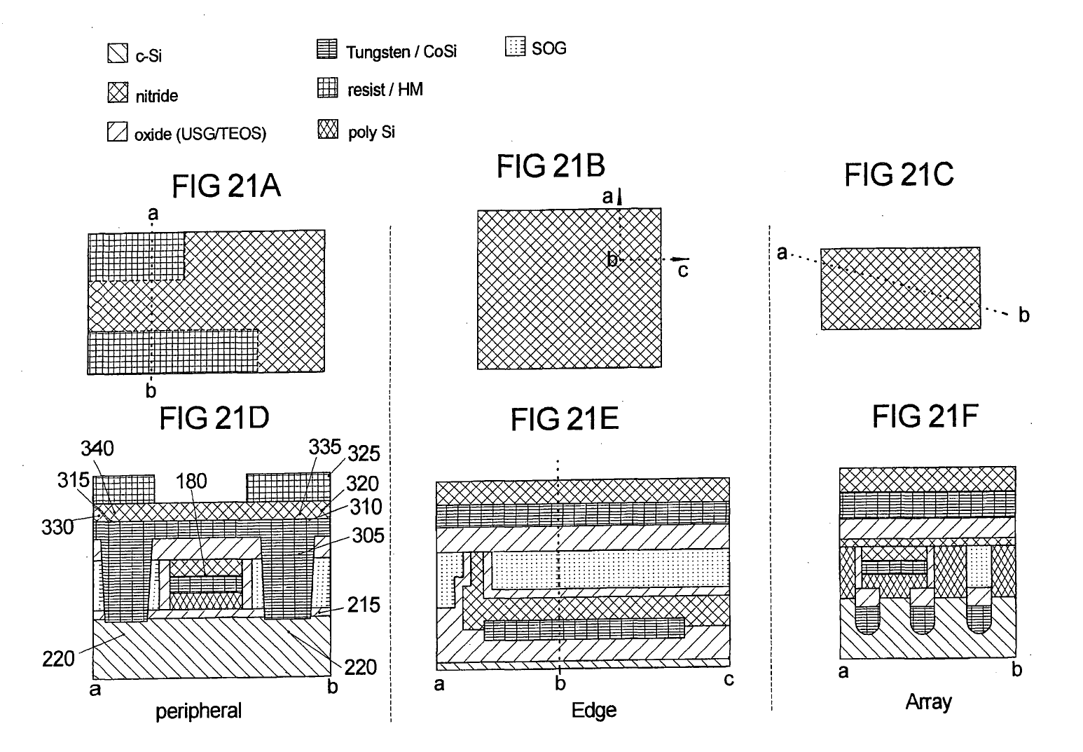

Afterwards, a third conductive layer 305 is fabricated, which is located directly above and in contact with the exposed gate contact pad 180 (FIG. 20D in combination with FIG. 21D). The third conductive layer 305 also contacts the CoSi-contacts 215 on top of the source/drain areas 220 and forms source and drain contact pads 310 and 315.

In order to separate the gate contact pads 180 from the source and drain contact pads 310 and 315, the third conductive layer 305 is subjected to an etch step using a nitride layer 320 and a resist or hard mask 325 (FIG. 21D). As the nitride layer 320 is situated on top of the third conductive layer 305 it also forms a third protection layer 330 and third protective caps 335 and 340 on top of the source/drain contact pads 310 and 315.

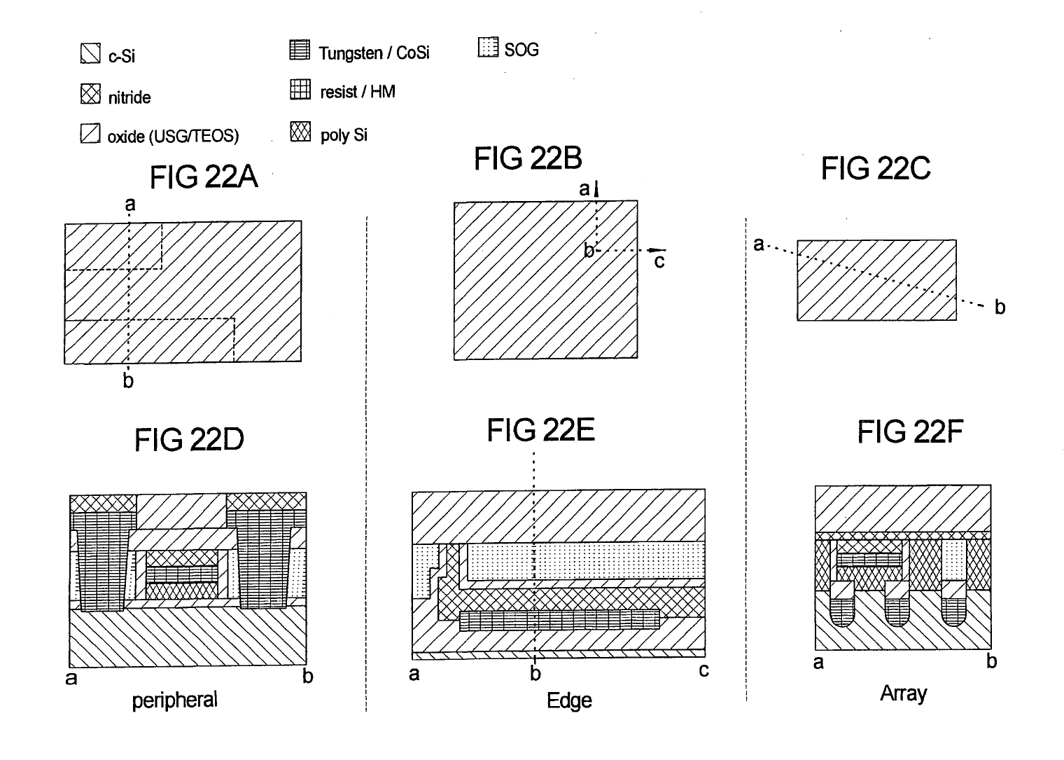

Then, the third protection layer 330 and the underlying third conductive layer 305 are etched such that the gate contact pad 180, the source contact pad 310 and the drain contact pad 315 are electrically separated from another (FIG. 22D).

On this structure an intermediate layer 255 is deposited and the structure further processed as explained above with regard to the first embodiment of the invention (see FIGS. 15A-16F). The intermediate layer 255 is etched using an etch mask exposing the first protective cap 150, the second protective cap 165, the additional protective cap 181 and both third protective caps 335 and 340 during the same etch step. After exposing the protective caps, all of them are etched and all underlying contact pads 85, 160, 180, 310 and 315 are exposed during the same etch step. Then a single metallization layer 265 may be used for completing the metallization and contact structure for the memory device 1.

What is claimed is:

1. Method of fabricating a semiconductor device, the method comprising:
fabricating a first conductive layer including a first contact pad and covering the first conductive layer with a first protection layer at least on top of the first contact pad such that a first protective cap is formed thereon;
fabricating a second conductive layer including a second contact pad, wherein the second conductive layer and the first conductive layer are electrically insulated from one another, and covering the second conductive layer with a second protection layer at least on top of the second contact pad such that a second protective cap is formed thereon;
depositing at least one intermediate layer on top of the structure;
forming a mask on top of the intermediate layer and etching the intermediate layer thereby exposing the first protective cap and the second protective cap, wherein an etchant is applied that provides a larger etch rate with regard to the intermediate layer than with regard to the protective layer; and
after exposing the first and second protective caps, etching them and exposing the first and second contact pad during the same etch step.

2. The method according to claim 1 wherein the first protection layer and the second protection layer are fabricated simultaneously during the same fabrication step.

3. The method according to claim 2 wherein the semiconductor device is fabricated in or on a substrate such that the first conductive layer and the second conductive layer have different distances relative to the substrate's surface.

4. The method according to claim 3 wherein the first conductive layer is fabricated inside the substrate below the substrate's surface.

5. The method according to claim 4 wherein the second conductive layer is fabricated above the substrate's surface.

6. The method according to claim 5 wherein the semiconductor device is a memory device comprising an array part with a plurality of memory cells.

7. The method according to claim 6 wherein the first conductive layer forms a buried word line of the memory device and the first contact pad forms a buried word line contact pad.

8. The method according to claim 7 wherein the second conductive layer forms a bit line of the memory device and the second contact pad forms a bit line contact pad.

9. The method according to claim 8 wherein the second conductive layer simultaneously forms a gate contact layer of at least one transistor of a driving circuit being placed in a peripheral part of the substrate located outside the array part, the gate contact layer including a gate contact pad.

10. The method according to claim 9 further comprising:
covering the second conductive layer with the second protection layer also on top of the gate contact pad such that an additional protective cap is formed thereon;
etching the intermediate layer and exposing the first protective cap, the second protective cap and the additional protective cap during the same etch step; and
after exposing said protective caps, etching all of them and exposing all contact pads during the same etch step.

11. The method according to claim 10 further comprising:
fabricating a third conductive layer including source and drain contact pads for the at least one transistor of the driving circuit; and
covering the third conductive layer with a third protection layer at least on top of the source and drain contact pads such that third protective caps are formed thereon.

12. The method according to claim 11 wherein the third conductive layer is fabricated such that the upper surface of the third conductive layer is located further apart from the substrate's surface than the upper surface of the first and second conductive layers.

13. The method according to claim 12 further comprising:
depositing the intermediate layer on top of the third protection layer;
structuring the intermediate layer and exposing the first protective cap, the second protective cap, the additional protective cap and both third protective caps during the same etch step; and
after exposing said protective caps, etching all of them and exposing all underlying contact pads during the same etch step.

14. The method according to claim 13 wherein the source and drain contacts of the at least one transistor of the driving circuit are fabricated in a self-aligned fashion using a sacrificial layer consisting of or containing polysilicon, amorphous silicon, SiGe-material and/or carbon.

15. The method according to claim 12 further comprising:
etching the second protective layer using an etch mask and exposing the gate contact pad at least partly before the third conductive layer is fabricated enabling the third conductive layer to be located directly above and in contact with the exposed gate contact pad; and
covering the third conductive layer with the third protection layer also at least on top of the gate contact pad.

16. The method according to claim 15 wherein the third protection layer and the underlying third conductive layer are etched such that the gate contact pad, the source contact pad and the drain contact pad are electrically separated from another before depositing the intermediate layer.

17. The method according to claim 16 wherein:
after depositing the intermediate layer this layer is etched using an etch mask exposing the first protective cap, the second protective cap, the additional protective cap and both third protective caps during the same etch step; and
after exposing said protective caps, etching all of them and exposing all underlying contact pads during the same etch step.

18. The method according to claim 11 wherein the first protection layer and the second protection layer are fabricated simultaneously and the third protection layer is fabricated thereafter.

19. The method according to claim 11 wherein the first protective layer, the second protective layer and the third protective layer consist of or contain silicon nitride.

20. The method according to claim 1 wherein the first protective layer and the second protective layer consist of or contain silicon nitride.

21. The method according to claim 1 wherein the intermediate layer consists of or contains silicon oxide.
